(19) United States
(12) Patent Application Publication
(10) Pub. No.: US 2022/0291589 A1
(43) Pub. Date: Sep. 15, 2022

(54) SCANNING ELECTRON MICROSCOPIC DIRECT-WRITE LITHOGRAPHY SYSTEM BASED ON A COMPLIANT NANO SERVO MOTION SYSTEM

(71) Applicant: Tsinghua University, Beijing (CN)

(72) Inventors: Zhen ZHANG, Beijing (CN); Yijie LIU, Beijing (CN); Juntian QU, Beijing (CN)

(21) Appl. No.: 17/664,672

(22) Filed: May 24, 2022

Related U.S. Application Data
(63) Continuation of application No. PCT/CN2022/072564, filed on Jan. 18, 2022.

(30) Foreign Application Priority Data
Jan. 28, 2021 (CN) 202110116772.1

(51) Int. Cl. G03F 7/20

(52) U.S. Cl. CPC G03F 7/704; G03F 7/2059

(57) ABSTRACT

The present application discloses a scanning electron microscopic direct-write lithography system based on a compliant nano servo motion system, which includes an electron chamber, an ion chamber, a specimen chamber and a control system, wherein the electron chamber includes an electron chamber housing, an electron gun, an anode, an electron beam blanker, an electromagnetic lens and an electron beam deflection coil, the ion chamber includes an ion chamber housing, an ion source, an ion beam-scanning deflection electrode and the like, the specimen chamber includes a specimen chamber housing, a secondary electron detector, a nanoscale-precision compliant servo motion stage system and the like; control system includes a computer, an electron beam scanning controller, an ion beam scanning controller and the like. An electron beam generated by the electron chamber and an ion beam generated by the ion chamber can each perform the nano direct-write fabrication, and the nanoscale-precision compliant motion stage in the specimen chamber can perform synchronized motions with the electron beam/ion beam, thereby, stitching errors are prevented from occurring in the direct-write fabrication, and thus nano direct-write lithographic fabrication can be implemented on a large area without a stitching error. In addition, the system is capable of performing an in-situ inspection during the fabrication process, thereby facilitating the real-time observation on the result of the fabrication.

### CROSS-REFERENCE TO RELATED APPLICATION(S)

This application is a continuation of co-pending International Patent Application No. PCT/CN2022/072564, filed on Jan. 18, 2022, which claims the priority and benefit of Chinese patent application number 202110116772.1, filed Jan. 28, 2021 with China National Intellectual Property Administration, the entire contents of which are incorporated herein by reference.

### TECHNICAL FIELD

The present application relates to the field of the direct-write fabrication of semiconductor integrated circuits, and particularly relates to a scanning electron microscopic direct-write lithography system based on a compliant nano servo motion system.

### BACKGROUND

At present, lithography is the main way to implement nanofabrication. The feature size in lithography is mainly limited by the wavelength of the light source, and it is relatively difficult to achieve a ten-nanometer-scale fabrication by lithography. General electron-beam and ion-beam lithography techniques have the following characteristics: the fabrication linewidth can reach a scale of several nanometers; the writing field is of a very limited size (about 100 microns); when required to fabricate a nanoscale-precision pattern on a large area, the specimen needs to be moved manually or by being driven by a stepper motor so as to perform the fabrication in writing fields one by one; there are significant stitching errors between different writing fields.

The existing electron beam lithography machine mainly includes an electron emitting gun, a confinement aperture, a plurality of confinement magnets, a magnetic field deflection coil, a deflection electric field generation device, a lithography mask and a wafer platen. In this type of electron beam lithography machine, a lithography mask is disposed between a wafer platen and an electron generation device to shield the electron beams which are not in the path of the lithographic pattern, thereby, the accuracy of lithography can be effectively improved. The dual electron-path-confinement facility allows for both the deflection electric field and the deflection magnetic field to be disposed in the passing path of the electrons, thereby, the direction of the electrons can be more accurately controlled.

The disadvantages of the above electron beam lithography machine are as follows: 1) Lithography masks are required, thus resulting in a relatively high fabrication cost; 2) The in-situ measurement is not available; 3) The large-area fabrication is difficult to be realized because of the relatively small writing field; 4) There are stitching errors in the fabrication process using different writing fields.

### SUMMARY OF THE INVENTION

### (i) The Technical Problem to be Solved

The present application is intended to solve at least one technical problem in the conventional art or related art. Thus, an objective of the present application is to provide a scanning electron microscopic lithography system that enables synchronized fabrication by using the electron beam/ion beam and the nanoscale-precision compliant servo motion stage system in a synchronized way, and enables direct-write fabrication without a stitching error within the scope of synchronized motions.

### (ii) Technical Solutions

In order to solve the above technical problem, the present application provides a scanning electron microscopic direct-write lithography system based on a compliant nano servo motion system, which includes an electron chamber, an ion chamber, a specimen chamber and a control system. Here, the electron chamber, being fixedly connected to the specimen chamber, includes an electron chamber housing, an electron gun, an anode, an electron beam blanker, an electromagnetic lens and an electron beam deflection coil; the ion chamber, being fixedly connected to the specimen chamber, includes an ion chamber housing, an ion source, a suppression electrode, an extraction electrode, a primary lens, an ion beam shutter editor, an ion beam shutter-shielding iris, a secondary lens and an ion beam-scanning deflection electrode; the specimen chamber includes a specimen chamber housing, a secondary electron detector, a nanoscale-precision compliant servo motion stage system, a specimen, a telescopic feeding mechanism, a vacuuming device and a base; and the control system includes a computer, an electron beam scanning controller, an electron beam blanker controller, an ion beam scanning controller, an ion beam shutter controller and a compliant stage execution unit driver. The scanning electron microscopic direct-write lithography system based on a compliant nano servo motion system includes two modes, namely, a fabrication mode and an in-situ inspection mode, and the computer controls a switching between the two modes. In the fabrication mode, the electron beam deflection coil energized with electric current deflects an electron beam generated by the electron gun to perform a scan, or the ion beam-scanning deflection electrode energized with electric current deflects an ion beam generated by the ion source to perform a scan, and the nanoscale-precision compliant servo motion stage system drives the specimen to perform a motion, wherein the electron beam deflection coil or the ion beam-scanning deflection electrode is operated as a first sub-system and the nanoscale-precision compliant servo motion stage system is operated as a second sub-system, a fabrication pattern is drawn or imported by the computer and is intelligently allocated to the first sub-system and the second sub-system by the computer to be used as a reference trajectory, and the first and second sub-systems perform synchronized motions to implement a non-stitching direct-write nanofabrication. In the inspection mode, the electron beam deflection coil energized with electric current causes an electron beam to scan a surface of the specimen, wherein electrons reflected from the surface of the specimen are configured to be detected by the secondary electron detector and form an image on the computer in order to perform an in-situ inspection.

Wherein, the electron gun, the anode, the electron beam blanker, the electromagnetic lens and the electron beam deflection coil may be disposed inside the electron chamber housing, and may be sequentially arranged from top to bottom. An electron emitted from the electron gun may pass sequentially through areas in which the anode, the electron beam blanker, the electromagnetic lens and the electron beam deflection coil are respectively disposed, and may eventually interact with the specimen. The ion source, the suppression electrode, the extraction electrode, the primary lens, the ion beam shutter editor, the ion beam shutter-shielding iris, the secondary lens and the ion beam-scanning deflection electrode may be disposed inside the ion chamber housing, and may be sequentially arranged from top to bottom. An ion generated by the ion source may pass sequentially through areas in which the ion source, the suppression electrode, the extraction electrode, the primary lens, the ion beam shutter editor, the ion beam shutter-shielding iris, the secondary lens and the ion beam-scanning deflection electrode are respectively disposed, and may eventually interact with the specimen.

Wherein, the electron beam deflection coil may include at least two pairs of coils and the ion beam-scanning deflection electrode may include at least two pairs of electrodes to perform a planar scan in both an X-direction and a Y-direction.

Wherein, a first end of the electron beam scanning controller may be connected with the computer to receive an instruction sent from the computer, and a second end of the electron beam scanning controller may be connected with the electron beam deflection coil to control a deflection of the electron beam. A first end of the electron beam blanker controller may be connected with the computer to receive an instruction sent from the computer, and a second end of the electron beam blanker controller may be connected with the electron beam blanker to control an on/off state of the electron beam.

Wherein, a first end of the ion beam scanning controller may be connected with the computer to receive an instruction sent from the computer, and a second end of the ion beam scanning controller may be connected with the ion beam-scanning deflection electrode to control a deflection of the ion beam. A first end of the ion beam shutter controller may be connected with the computer to receive an instruction sent from the computer, and a second end of the ion beam shutter controller may be connected with the ion beam shutter editor to control an on/off state of the ion beam.

Wherein, a first end of the compliant stage execution unit driver may be connected with the computer to receive an instruction sent from the computer, and a second end of the compliant stage execution unit driver may be connected with an execution unit in the nanoscale-precision compliant servo motion stage system to drive a compliant stage to perform a scan motion.

Wherein, the nanoscale-precision compliant servo motion stage system may be a nanoscale-precision compliant servo motion stage system driven by a voice coil motor on the basis of a leaf spring, and may include a nanoscale-precision compliant motion stage, a voice-coil-motor coil, a voice-coil-motor coil support, a voice-coil-motor moving magnet and a voice-coil-motor moving magnet support. A first end of the voice-coil-motor coil support may be connected with the voice-coil-motor coil, and a second end of the voice-coil-motor coil support may be connected with the base. A first end of the voice-coil-motor moving magnet support may be connected with the voice-coil-motor moving magnet, and a second end of the voice-coil-motor moving magnet support may be connected with a motion end of the nanoscale-precision compliant motion stage.

Wherein, the voice-coil-motor moving magnet and the voice-coil-motor coil may be separated by a motor heat insulation shield hood. The voice-coil-motor moving magnet may be disposed inside the specimen chamber housing. The voice-coil-motor coil may be disposed outside the specimen chamber housing.

Wherein, the scanning electron microscopic direct-write lithography system based on a compliant nano servo motion system may further include a laser interferometer for feeding back an actual displacement of the nanoscale-precision compliant motion stage to perform a closed-loop feedback control.

Wherein, the scanning electron microscopic direct-write lithography system based on a compliant nano servo motion system may further include a sight window that is disposed over the specimen chamber housing and used for observing an internal state of the specimen chamber housing.

In order to solve the above technical problem, the present application further provides a scanning electron microscopic direct-write lithography system based on a compliant nano servo motion system, which includes an electron chamber, an ion chamber, a specimen chamber and a control system. Here, the electron chamber includes an electron beam deflection coil, the ion chamber includes an ion beam-scanning deflection electrode, the specimen chamber includes a nanoscale-precision compliant servo motion stage system, and the control system includes a computer. The scanning electron microscopic direct-write lithography system based on a compliant nano servo motion system includes two modes, namely, a fabrication mode and an in-situ inspection mode, and the computer controls a switching between the two modes. In the fabrication mode, the electron beam deflection coil energized with electric current deflects an electron beam generated by the electron gun to perform a scan, or the ion beam-scanning deflection electrode energized with electric current deflects an ion beam generated by the ion source to perform a scan, and the nanoscale-precision compliant servo motion stage system drives the specimen to perform a motion, wherein the electron beam deflection coil or the ion beam-scanning deflection electrode is operated as a first sub-system and the nanoscale-precision compliant servo motion stage system is operated as a second sub-system, a pattern, to be used as a reference trajectory, is intelligently allocated to the first sub-system and the second sub-system by the computer, the first and second sub-systems perform synchronized motions to implement a non-stitching direct-write nanofabrication. In the inspection mode, the electron beam deflection coil energized with electric current causes an electron beam to scan a surface of the specimen to perform an in-situ inspection.

### (iii) Beneficial Effects

As compared to the conventional art, the present application at least provides advantages as follows:

The present application provides a scanning electron microscopic direct-write lithography system based on a compliant nano servo motion system, which forms a direct-write lithographic system essentially constituted by an electron chamber, an ion chamber, a specimen chamber and a control system. Wherein, an electron beam generated by the electron chamber and an ion beam generated by the ion chamber can each perform a direct-write nanofabrication, and the nanoscale-precision compliant motion stage in the specimen chamber can perform synchronized motions with the electron beam/ion beam, thereby, stitching errors are prevented from occurring in the direct-write fabrication, and thus nano direct-write lithographic fabrication can be implemented on a large area without a stitching error. In addition, the system is capable of performing an in-situ inspection during the fabrication process, thereby facilitating the real-time observation on the result of the fabrication.

### BRIEF DESCRIPTION OF THE DRAWINGS

For more clearly illustrating the technical solutions in embodiments of the present disclosure or in the conventional art, the accompanying drawings, which are needed for describing the embodiments or the conventional art, will be briefly introduced hereinafter. Apparently, the accompanying drawings described below refer merely to some embodiments of the present disclosure, and other drawings can be acquired, by those skilled in the art without making any creative effort, based on the accompanying drawings illustrated herein.

FIG. 1 is a schematic structural diagram of a scanning electron microscopic direct-write lithography system based on a compliant nano servo motion system according to an embodiment of the present application.

FIG. 2 is a local sectional view of a scanning electron microscopic direct-write lithography system based on a compliant nano servo motion system according to an embodiment of the present application.

FIG. 3 is a sectional view of an electron chamber and an ion chamber in a scanning electron microscopic direct-write lithography system based on a compliant nano servo motion system according to an embodiment of the present application.

FIG. 4 is a sectional view of a nanoscale-precision compliant motion stage and a motor in a scanning electron microscopic direct-write lithography system based on a compliant nano servo motion system according to an embodiment of the present application.

### DESCRIPTION OF REFERENCE NUMERALS

100: electron chamber, 200: specimen chamber, 300: ion chamber,
101: electron chamber housing, 102: electron gun, 103: anode,
104: electron beam blanker, 105: electromagnetic lens,
106: electron beam deflection coil, 201: specimen chamber housing,
202: secondary electron detector, 203: nanoscale-precision compliant motion stage,
204: sight window, 205: base, 206: specimen,
207: voice-coil-motor coil support,
208: voice-coil-motor moving moving magnet support, 209: voice-coil-motor coil,
210: voice-coil-motor moving moving magnet, 211: motor heat insulation shield hood,
212: telescopic feeding mechanism, 301: ion chamber housing, 302: ion source,
303: suppression electrode, 304: extraction electrode, 305: primary lens,
306: ion beam shutter editor, 307: ion beam shutter: shielding iris,
308: secondary lens, 309: ion beam-scanning deflection electrode.

### DETAILED DESCRIPTION OF EMBODIMENTS

A further detailed description of the specific embodiments of the present application will be presented hereinafter by reference to the accompanying drawings and the embodiments. The following instances are intended to illustrate the present application and are not intended to limit the scope of the present application.

In the description of the present application, it should be noted that, unless otherwise stated, the term “plurality” denotes two or more. Directions or positional relationships indicated by the terms “upper,” “lower,” “left,” “right,” “inside,” “outside,” “front end,” “rear end,” “header,” “tailer” and the like are based on the directions or positional relationship illustrated in the accompanying drawings, which are merely for the purpose of facilitating the description of the present application and simplifying the description and are not indicative or suggestive of the corresponding device or element necessarily being in or being constructed/operated in a specific orientation, and thus these terms are not to be understood as a limitation on the present application. In addition, the terms “first,” “second,” “third” and the like are used for descriptive purposes only and are not to be understood as being indicative or suggestive of relative importance.

In the description of the present application, it should be noted that, unless otherwise specified or limited, the terms “installed,” “joined,” “coupled” or the like should be broadly understood, for instance, it may be a fixed connection, a detachable connection or an integral connection, may be a mechanical connection or an electrical connection, may be a direct connection or an indirect connection via an intermediate medium, or otherwise may be an interior communication between two elements. For those skilled in the art, specific meanings of the above terms in the present application can be understood according to the specific circumstances thereof.

### Embodiment 1

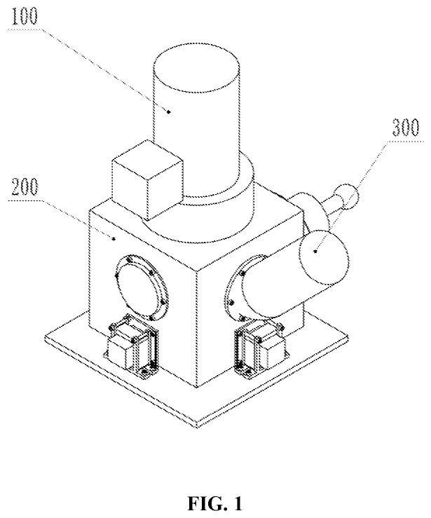

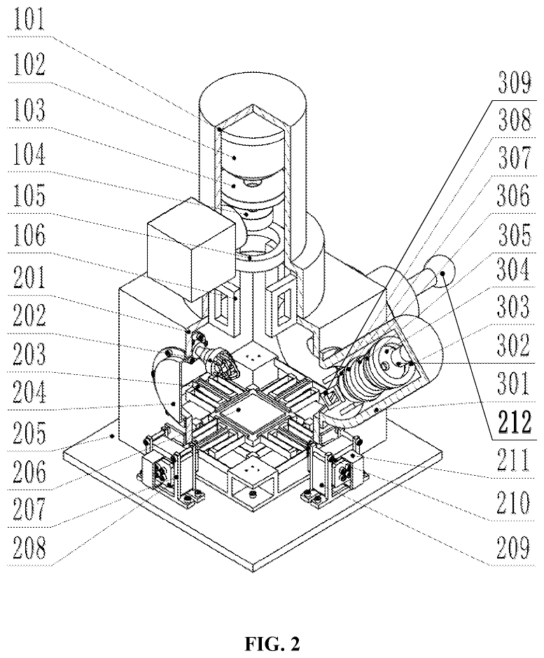

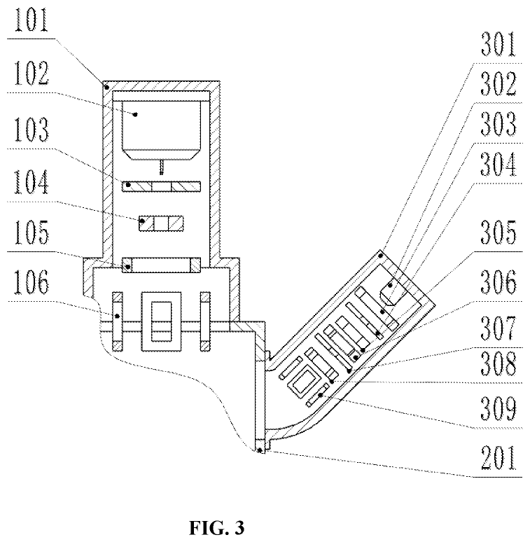

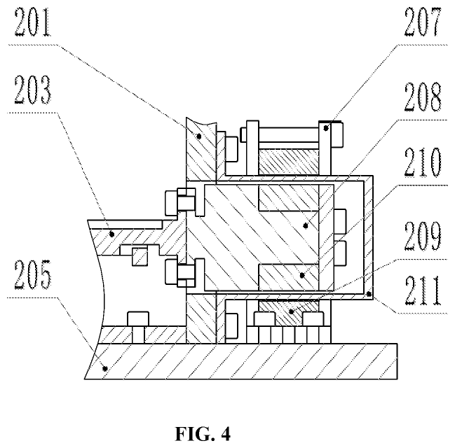

As shown in FIGS. 1 to 4, a scanning electron microscopic direct-write lithography system based on a compliant nano servo motion system provided in the present embodiment includes an electron chamber 100, an ion chamber 300, a specimen chamber 200 and a control system.

The electron chamber 100 includes an electron chamber housing 101, an electron gun 102, an anode 103, an electron beam blanker 104, an electromagnetic lens 105 and an electron beam deflection coil 106. The electron chamber 100 is fixedly connected to the specimen chamber 200. The ion chamber 300 includes an ion chamber housing 301, an ion source 302, a suppression electrode 303, an extraction electrode 304, a primary lens 305, an ion beam shutter editor 306, an ion beam shutter-shielding iris 307, a secondary lens 308 and an ion beam-scanning deflection electrode 309. The ion chamber 300 is fixedly connected to the specimen chamber 200. The specimen chamber 200 includes a specimen chamber housing 201, a secondary electron detector 202, a nanoscale-precision compliant servo motion stage system, a specimen 206, a telescopic feeding mechanism 212, a vacuuming device and a base 205. The control system includes a computer, an electron beam scanning controller, an electron beam blanker controller, an ion beam scanning controller, an ion beam shutter controller and a compliant stage execution unit driver.

In the present embodiment, the scanning electron microscopic direct-write lithography system based on a compliant nano servo motion system may include two modes, namely, a fabrication mode and an in-situ inspection mode, and the computer may control a switching between the two modes. In the fabrication mode, the electron beam deflection coil 106 energized with electric current may deflect an electron beam generated by the electron gun 102 to perform a scan, or the ion beam-scanning deflection electrode 309 energized with electric current may deflect an ion beam generated by the ion source 302 to perform a scan, and the nanoscale-precision compliant servo motion stage system may drive the specimen to perform a motion. A fabrication pattern may be drawn or imported by the computer and may be intelligently allocated, by the computer, to the electron beam deflection coil 106/the ion beam-scanning deflection electrode 309 and the nanoscale-precision compliant servo motion stage system to be used as a reference trajectory according to which the sub-systems move, thereby, a non-stitching direct-write nanofabrication can be implemented by synchronized motions of the two sub-systems. In the inspection mode, the electron beam deflection coil 106 energized with electric current may cause an electron beam to scan a surface of the specimen 206. Electrons reflected from the surface of the specimen 206 may be detected by the secondary electron detector 202 and may form an image on the computer in order to perform an in-situ fabrication and inspection.

Hereinafter, a further detailed description will be given by describing the detailed process.

The electron gun 102, the anode 103, the electron beam blanker 104, the electromagnetic lens 105 and the electron beam deflection coil 106 may be disposed inside the electron chamber housing 101 and may be sequentially arranged from top to bottom. An electron emitted from the electron gun 102 may pass sequentially through areas in which the anode 103, the electron beam blanker 104, the electromagnetic lens 105 and the electron beam deflection coil 106 are respectively disposed, and may eventually interact with the specimen 206. The ion source 302, the suppression electrode 303, the extraction electrode 304, the primary lens 305, the ion beam shutter editor 306, the ion beam shutter-shielding iris 307, the secondary lens 308 and the ion beam-scanning deflection electrode 309 may be disposed inside the ion chamber housing 301, and may be sequentially arranged from top to bottom. An ion generated by the ion source 302 may pass sequentially through areas in which the ion source 302, the suppression electrode 303, the extraction electrode 304, the primary lens 305, the ion beam shutter editor 306, the ion beam shutter-shielding iris 307, the secondary lens 308 and the ion beam-scanning deflection electrode 309 are respectively disposed, and may eventually interact with the specimen 206.

In the present embodiment, the electron beam deflection coil 106 may include at least two pairs of coils and the ion beam-scanning deflection electrode 309 may include at least two pairs of electrodes to perform a planar scan in both an X-direction and a Y-direction.

Further, a first end of the electron beam scanning controller may be connected with the computer to receive an instruction sent from the computer, and a second end of the electron beam scanning controller may be connected with the electron beam deflection coil 106 to control a deflection of the electron beam. A first end of the electron beam blanker controller may be connected with the computer to receive an instruction sent from the computer, and a second end of the electron beam blanker controller may be connected with the electron beam blanker 104 to control an on/off state of the electron beam.

Further, a first end of the ion beam scanning controller may be connected with the computer to receive an instruction sent from the computer, and a second end of the ion beam scanning controller may be connected with the ion beam-scanning deflection electrode 309 to control a deflection of the ion beam. a first end of the ion beam shutter controller may be connected with the computer to receive an instruction sent from the computer, and a second end of the ion beam shutter controller may be connected with the ion beam shutter editor 306 to control an on/off state of the ion beam.

Further, a first end of the compliant stage execution unit driver may be connected with the computer to receive an instruction sent from the computer, and a second end of the compliant stage execution unit driver may be connected with an execution unit in the nanoscale-precision compliant servo motion stage system to drive a compliant stage to perform a scan motion.

Specifically, in the present embodiment, the nanoscale-precision compliant servo motion stage system may be a nanoscale-precision compliant servo motion stage system driven by a voice coil motor on the basis of a leaf spring and may include a nanoscale-precision compliant motion stage 203, a voice-coil-motor coil 209, a voice-coil-motor coil support 207, a voice-coil-motor moving magnet 210 and a voice-coil-motor moving magnet support 208. A first end of the voice-coil-motor coil support 207 may be connected with the voice-coil-motor coil 209 and a second end of the voice-coil-motor coil support 207 may be connected with the base 205. A first end of the voice-coil-motor moving magnet support 208 may be connected with the voice-coil-motor moving magnet 210 and a second end of the voice-coil-motor moving magnet support 208 may be connected with a motion end of the nanoscale-precision compliant motion stage 203.

Preferably, the voice-coil-motor moving magnet 210 and the voice-coil-motor coil 209 may be separated by a motor heat insulation shield hood 211. The voice-coil-motor moving magnet 210 may be disposed inside the specimen chamber housing 201. The voice-coil-motor coil 209 may be disposed outside the specimen chamber housing 201.

Specifically, in the present embodiment, the computer may control the electron beam deflection coil 106 and the nanoscale-precision compliant motion stage 203 to perform synchronized motions, thereby enabling a nano direct-write fabrication on a large area without a stitching error.

Further, after the completion of the fabrication, the computer may control the electron beam deflection coil 106 to cause the electron beam to perform a scan motion, thereby enabling an in-situ inspection on the specimen 206 after being fabricated.

The present embodiment provides a scanning electron microscopic direct-write lithography system based on a compliant nano servo motion system, which may form a direct-write lithographic system essentially constituted by an electron chamber, an ion chamber, a specimen chamber and a control system. An electron beam generated by the electron chamber and an ion beam generated by the ion chamber can each perform a direct-write nanofabrication, and the nanoscale-precision compliant motion stage in the specimen chamber can perform synchronized motions with the electron beam/ion beam, thereby, stitching errors are prevented from occurring in the direct-write fabrication, and thus nano direct-write lithographic fabrication can be implemented on a large area without a stitching error. In addition, the scanning electron microscopic direct-write lithography system based on a compliant nano servo motion system provided in the present embodiment is capable of performing an in-situ inspection on the fabricated specimen, thereby facilitating the observation on the result of the fabrication.

### Embodiment 2

The present embodiment is substantially the same as EMBODIMENT 1, and thus, for the conciseness of the description, only the differences from EMBODIMENT 1 will be described in the description of the present embodiment, while the technical features identical to those in EMBODIMENT 1 will not be repeatedly described.

Furthermore, a laser interferometer for feeding back an actual displacement of the nanoscale-precision compliant motion stage may be further included in the scanning electron microscopic direct-write lithography system based on a compliant nano servo motion system to perform a closed-loop feedback control.

Further, a sight window may be further included in the scanning electron microscopic direct-write lithography system based on a compliant nano servo motion system. The sight window may be disposed over the specimen chamber housing and used for observing an internal state of the specimen chamber housing.

In the scanning electron microscopic direct-write lithography system based on a compliant nano servo motion system provided in the present embodiment, an ion beam can be used in the fabrication, and meanwhile an electron beam can be used in a real-time inspection on the result of the fabrication. The way of fabrication and inspection in details is as follows:

The ion beam-scanning deflection electrode 309 and the nanoscale-precision compliant motion stage 203 may be controlled by the computer to perform synchronized motions (combined motions), thereby enabling a nano direct-write fabrication on a large area without a stitching error. Meanwhile, the electron beam deflection coil 106 may be controlled by the computer to perform a high-speed scan on the specimen 206, and the secondary electrons reflected from the surface of the specimen may be collected by the secondary electron detector 202 to form an image in order to perform a real-time inspection on the result of the direct-write lithographic fabrication.

What is described above is merely some preferred embodiments of the present application and is not intended to limit the present application. Any modification, equivalent substitution, improvement or the like that is made within the gist and principles of the present application shall all be included within the protection scope of the present application.

We claim:

1. A scanning electron microscopic direct-write lithography system based on a compliant nano servo motion system, comprising an electron chamber, an ion chamber, a specimen chamber and a control system, wherein:
the electron chamber, being fixedly connected to the specimen chamber, comprises an electron chamber housing, an electron gun, an anode, an electron beam blanker, an electromagnetic lens and an electron beam deflection coil;
the ion chamber, being fixedly connected to the specimen chamber, comprises an ion chamber housing, an ion source, a suppression electrode, an extraction electrode, a primary lens, an ion beam shutter editor, an ion beam shutter-shielding iris, a secondary lens and an ion beam-scanning deflection electrode;
the specimen chamber comprises a specimen chamber housing, a secondary electron detector, a nanoscale-precision compliant servo motion stage system, a specimen, a telescopic feeding mechanism, a vacuuming device and a base; and
the control system comprises a computer, an electron beam scanning controller, an electron beam blanker controller, an ion beam scanning controller, an ion beam shutter controller and a compliant stage execution unit driver,
and wherein the scanning electron microscopic direct-write lithography system based on a compliant nano servo motion system comprises two modes, namely, a fabrication mode and an in-situ inspection mode, and the computer controls a switching between the two modes:
in the fabrication mode, the electron beam deflection coil energized with electric current deflects an electron beam generated by the electron gun to perform a scan, or the ion beam-scanning deflection electrode energized with electric current deflects an ion beam generated by the ion source to perform a scan, and the nanoscale-precision compliant servo motion stage system drives the specimen to perform a motion,
wherein the electron beam deflection coil or the ion beam-scanning deflection electrode is operated as a first sub-system and the nanoscale-precision compliant servo motion stage system is operated as a second sub-system, a fabrication pattern is drawn or imported by the computer and is intelligently allocated to the first sub-system and the second sub-system by the computer to be used as a reference trajectory, and the first and second sub-systems perform synchronized motions to implement a non-stitching direct-write nanofabrication; and
in the inspection mode, the electron beam deflection coil energized with electric current causes an electron beam to scan a surface of the specimen, wherein electrons reflected from the surface of the specimen are configured to be detected by the secondary electron detector and form an image on the computer in order to perform an in-situ inspection.

2. The scanning electron microscopic direct-write lithography system based on a compliant nano servo motion system according to claim 1, wherein:
the electron gun, the anode, the electron beam blanker, the electromagnetic lens and the electron beam deflection coil are disposed inside the electron chamber housing, and are sequentially arranged from top to bottom, wherein an electron emitted from the electron gun passes sequentially through areas in which the anode, the electron beam blanker, the electromagnetic lens and the electron beam deflection coil are respectively disposed, and eventually interacts with the specimen;
the ion source, the suppression electrode, the extraction electrode, the primary lens, the ion beam shutter editor, the ion beam shutter-shielding iris, the secondary lens and the ion beam-scanning deflection electrode are disposed inside the ion chamber housing, and are sequentially arranged from top to bottom, wherein an ion generated by the ion source passes sequentially through areas in which the ion source, the suppression electrode, the extraction electrode, the primary lens, the ion beam shutter editor, the ion beam shutter-shielding iris, the secondary lens and the ion beam-scanning deflection electrode are respectively disposed, and eventually interacts with the specimen.

3. The scanning electron microscopic direct-write lithography system based on a compliant nano servo motion system according to claim 1, wherein:
the electron beam deflection coil comprises at least two pairs of coils and the ion beam-scanning deflection electrode comprises at least two pairs of electrodes to perform a planar scan in both an X-direction and a Y-direction.

4. The scanning electron microscopic direct-write lithography system based on a compliant nano servo motion system according to claim 1, wherein:
a first end of the electron beam scanning controller is connected with the computer to receive an instruction sent from the computer, and a second end of the electron beam scanning controller is connected with the electron beam deflection coil to control a deflection of the electron beam; and
a first end of the electron beam blanker controller is connected with the computer to receive an instruction sent from the computer, and a second end of the electron beam blanker controller is connected with the electron beam blanker to control an on/off state of the electron beam.

5. The scanning electron microscopic direct-write lithography system based on a compliant nano servo motion system according to claim 1, wherein:
a first end of the ion beam scanning controller is connected with the computer to receive an instruction sent from the computer, and a second end of the ion beam scanning controller is connected with the ion beam-scanning deflection electrode to control a deflection of the ion beam; and
a first end of the ion beam shutter controller is connected with the computer to receive an instruction sent from the computer, and a second end of the ion beam shutter controller is connected with the ion beam shutter editor to control an on/off state of the ion beam.

6. The scanning electron microscopic direct-write lithography system based on a compliant nano servo motion system according to claim 1, wherein:
a first end of the compliant stage execution unit driver is connected with the computer to receive an instruction sent from the computer, and a second end of the compliant stage execution unit driver is connected with an execution unit in the nanoscale-precision compliant servo motion stage system to drive a compliant stage to perform a scan motion.

7. The scanning electron microscopic direct-write lithography system based on a compliant nano servo motion system according to claim 1, wherein:
the nanoscale-precision compliant servo motion stage system is a nanoscale-precision compliant servo motion stage system which is based on a leaf spring and is driven by a voice coil motor, and comprises a nanoscale-precision compliant motion stage, a voice-coil-motor coil, a voice-coil-motor coil support, a voice-coil-motor moving magnet and a voice-coil-motor moving magnet support, wherein
a first end of the voice-coil-motor coil support is connected with the voice-coil-motor coil and a second end of the voice-coil-motor coil support is connected with the base; and
a first end of the voice-coil-motor moving magnet support is connected with the voice-coil-motor moving magnet and a second end of the voice-coil-motor moving magnet support is connected with a motion end of the nanoscale-precision compliant motion stage.

8. The scanning electron microscopic direct-write lithography system based on a compliant nano servo motion system according to claim 7, wherein:
the voice-coil-motor moving magnet and the voice-coil-motor coil are separated by a motor heat insulation shield hood, the voice-coil-motor moving magnet is disposed inside the specimen chamber housing, and the voice-coil-motor coil is disposed outside the specimen chamber housing.

9. The scanning electron microscopic direct-write lithography system based on a compliant nano servo motion system according to claim 7, further comprising:
a laser interferometer for feeding back an actual displacement of the nanoscale-precision compliant motion stage to perform a closed-loop feedback control.

10. The scanning electron microscopic direct-write lithography system based on a compliant nano servo motion system according to claim 1, further comprising:
a sight window, the sight window being disposed over the specimen chamber housing and used for observing an internal state of the specimen chamber housing.

11. A scanning electron microscopic direct-write lithography system based on a compliant nano servo motion system, comprising an electron chamber, an ion chamber, a specimen chamber and a control system, wherein
the electron chamber comprises an electron beam deflection coil, the ion chamber comprises an ion beam-scanning deflection electrode, the specimen chamber comprises a nanoscale-precision compliant servo motion stage system, and the control system comprises a computer;
and wherein the scanning electron microscopic direct-write lithography system based on a compliant nano servo motion system comprises two modes, namely, a fabrication mode and an in-situ inspection mode, and the computer controls a switching between the two modes:
in the fabrication mode, the electron beam deflection coil energized with electric current deflects an electron beam generated by the electron gun to perform a scan, or the ion beam-scanning deflection electrode energized with electric current deflects an ion beam generated by the ion source to perform a scan, and the nanoscale-precision compliant servo motion stage system drives the specimen to perform a motion;
wherein the electron beam deflection coil or the ion beam-scanning deflection electrode is operated as a first sub-system and the nanoscale-precision compliant servo motion stage system is operated as a second sub-system, a pattern, to be used as a reference trajectory, is intelligently allocated to the first sub-system and the second sub-system by the computer, the first and second sub-systems perform synchronized motions to implement a non-stitching direct-write nanofabrication; and
in the inspection mode, the electron beam deflection coil energized with electric current causes an electron beam to scan a surface of the specimen to perform an in-situ inspection.
